(19) United States
(12) Patent Application Publication
(10) Pub. No.: US 2011/0100692 A1
(43) Pub. Date: May 5, 2011

(54) Circuit Board with Variable Topography Solder Interconnects

(76) Inventors: Roden Topacio, Markham (CA); Andrew Leung, Markham (CA)

(21) Appl. No.: 12/610,949

(22) Filed: Nov. 2, 2009

(51) Int. Cl. H05K 1/16; B23K 20/24; B23K 31/02; H05K 1/00; H05K 1/11

(52) U.S. Cl. 174/260; 228/203; 228/179.1; 174/250; 174/263

(57) ABSTRACT

Various circuit boards and methods of making the same are disclosed. In one aspect, a method of manufacturing is provided that includes applying a solder mask to a first side of a first circuit board. The first side of the first circuit board includes a first conductor structure and a second conductor structure. A first opening is formed in the solder mask that extends to the first conductor structure. The first opening has a first area. A second opening is formed in the solder mask that extends to the second conductor structure and has a second area larger than the first area.

### BACKGROUND OF THE INVENTION

1. Field of the Invention

This invention relates generally to semiconductor processing, and more particularly to circuit board solder interconnect systems and methods of making the same.

2. Description of the Related Art

A typical conventional flip-chip packaged semiconductor chip consists of a laminate of several layers of different materials. From bottom to top, a typical package consists of a base or carrier substrate, a die underfill material, an array of solder joints and the silicon die. For some designs, a thermal interface material and a lid or heat spreader top off the stack. In some designs the carrier substrate includes a ball grid array to connect to another circuit board. A conventional ball grid array consists of an array of solder balls of the same diameter partially inserted into respective openings in a solder mask. The openings have the same diameter. Each of the layers of the package generally has a different coefficient of thermal expansion (CTE). In some cases, the coefficients of thermal expansion for two layers, such as the underfill material and the silicon die, may differ by a factor of ten or more. Materials with differing CTE's strain at different rates during thermal cycling. The differential strain rates tend to produce warping of the package substrate and the silicon die. If the warping is severe enough, several undesirable things can occur.

One risk associated with carrier substrate warping is solder joint delamination. If the warping is severe enough, some of the solder joints between the die and the substrate can delaminate and cause electrical failure.

Another pitfall associated with substrate warping is the potential difficulty in establishing metallurgical bonds between the package substrate ball grid array and a complementary ball grid array on another circuit board, such as a circuit card. The warping causes the lower surfaces of the solder balls of the package ball grid array to be non-planar. Depending on the direction of warping, the balls at the outer edges of the ball array may be either higher or lower than those near the interior. If a given solder ball is too far away from a corresponding ball on the circuit board at the time of reflow, the two balls may not merge to form a solder joint and leave an open circuit.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes applying a solder mask to a first side of a first circuit board. The first side of the first circuit board includes a first conductor structure and a second conductor structure. A first opening is formed in the solder mask that extends to the first conductor structure. The first opening has a first area. A second opening is formed in the solder mask that extends to the second conductor structure and has a second area larger than the first area.

In accordance with another aspect of an embodiment of the present invention, a method of manufacturing is provided that includes applying a solder mask to a first side of a first circuit board. The first side of the first circuit board includes a first conductor structure and a second conductor structure. A first opening is formed in the solder mask that extends to the first conductor structure. A second opening is formed in the solder mask that extends to the second conductor structure. A first solder structure is coupled to the first conductor structure wherein the first solder structure is positioned at least partially in the first opening and includes a first surface projecting away from the solder mask a first distance. A second solder structure is coupled to the second conductor structure wherein the second solder structure is positioned at least partially in the second opening and includes a second surface projecting away from the solder mask a second distance greater than the first distance.

In accordance with another aspect of an embodiment of the present invention, an apparatus is provided that includes a first circuit board that has a first side and second side opposite the first side. The first side includes a first conductor structure and a second conductor structure. A solder mask is positioned on the first side and includes a first opening that extends to the first conductor structure and has a first area and a second opening that extends to the second conductor structure and has a second area larger than the first area.

In accordance with another aspect of an embodiment of the present invention, an apparatus is provided that includes a first circuit board that has a first side and a second side opposite the first side. The first side includes a first conductor structure and a second conductor structure. A solder mask is positioned on the first side and includes a first opening extending to the first conductor structure and a second opening extending to the second conductor structure. A first solder structure is coupled to the first conductor structure, positioned at least partially in the first opening, and includes a first surface projecting away from the solder mask a first distance. A second solder structure is coupled to the second conductor structure, positioned at least partially in the second opening and includes a second surface projecting away from the solder mask a second distance greater than the first distance.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary conventional semiconductor chip package that includes a semiconductor chip flip-chip mounted on a package substrate;

FIG. 2 is a sectional view of FIG. 1 taken at section 2-2;

FIG. 3 is a sectional view like FIG. 2 but depicting the initial mounting of the conventional semiconductor chip package to a circuit board;

FIG. 4 is a partially exploded sectional view of an exemplary embodiment of a semiconductor chip device that includes a semiconductor chip mounted to a circuit board;

FIG. 5 is a portion of FIG. 4 shown at greater magnification;

FIG. 6 is a portion of FIG. 4 shown at greater magnification but depicting pre-reflow solder ball attachment to the circuit board;

FIG. 7 is a sectional view of a small portion of an exemplary circuit board undergoing mask application;

FIG. 8 is a sectional view like FIG. 7 depicting solder mask developing to establish an exemplary opening;

FIG. 9 is an overhead view of the exemplary opening depicted in FIG. 8;

FIG. 10 is a partially exploded sectional view of an alternate exemplary embodiment of a semiconductor chip device that includes a semiconductor chip mounted to a circuit board;

FIG. 11 is a sectional view of an alternate exemplary embodiment of a semiconductor chip device that includes a semiconductor chip mounted to a circuit board; and

FIG. 12 is a sectional view of an alternate exemplary embodiment of a semiconductor chip device that includes a semiconductor chip mounted to a circuit board.

### DETAILED DESCRIPTION OF SPECIFIC EMBODIMENTS

Various embodiments of a circuit board are described herein. One example includes variable geometry solder interconnects. A solder mask includes openings with different areas so that solder structures, such as solder balls, positioned therein can expand laterally different amounts to make the lower surfaces of the balls somewhat coplanar. In this way, the impact of circuit board warping on ball-to-ball reflow is lessened. Additional details will now be described.

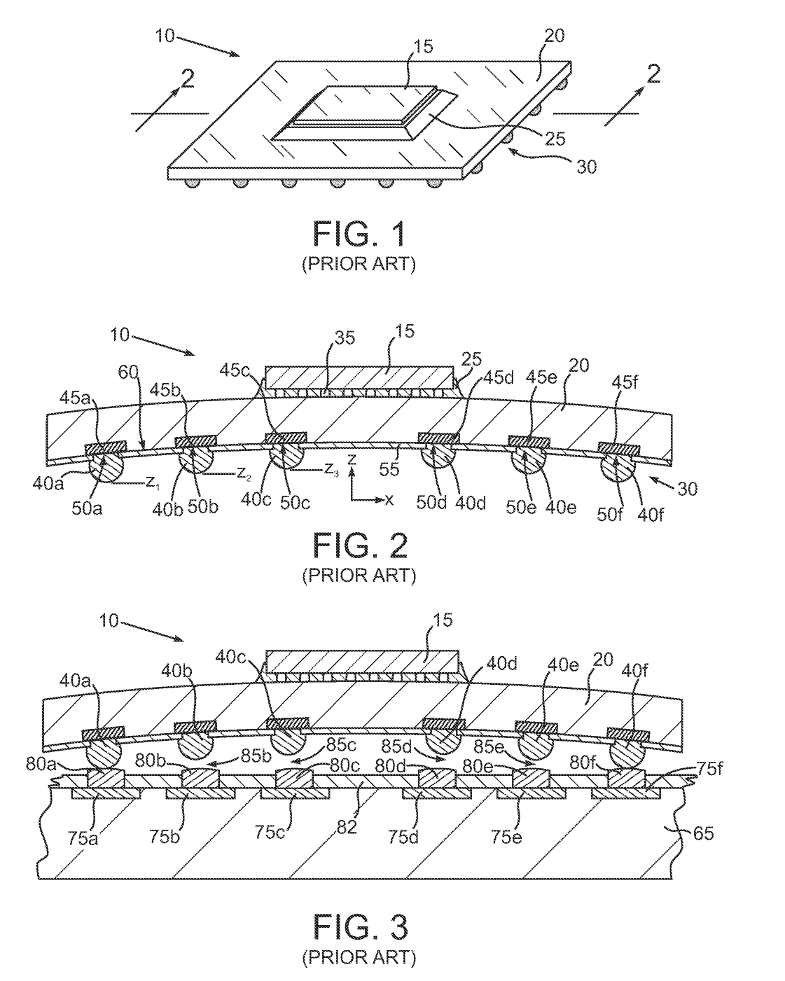

In the drawings described below, reference numerals are generally repeated where identical elements appear in more than one figure. Turning now to the drawings, and in particular to FIG. 1, therein is shown a pictorial view of an exemplary conventional semiconductor chip package 10 that includes a semiconductor chip 15 flip-chip mounted on a package substrate 20. The chip package 10 includes an underfill material layer 25 to lessen the effects of CTE mismatch. To interface with other devices such as a circuit board, the package substrate 20 is provided with a ball grid array labeled collectively 30.

Additional details of the conventional package 10 may be understood by referring now to FIG. 2, which is a sectional view of FIG. 1 taken at section 2-2. The semiconductor chip 15 is flip-chip mounted to the package substrate 20 and electrically connected thereto by way of plural solder joints 35. As noted above, the package 10 includes a underfill that partially encapsulates the semiconductor chip 15. Six solder balls of the ball grid array 30 are visible and labeled 40a, 40b, 40c, 40d, 40e and 40f, respectively. The solder balls 40a, 40b, 40c, 40d, 40e and 40f are metallurgically bonded to respective ball pads 45a, 45b, 45c, 45d, 45e and 45f. The solder balls 40a, 40b, 40c, 40d, 40e and 40f project through respective openings 50a, 50b, 50c, 50d, 50e and 50f in a solder mask 55 formed on a lower surface 60 of the package substrate 20. As noted in the Background section hereof, a conventional semiconductor chip package substrate is typically a complex laminate of one or more layers of polymer and interspersed with metallic interconnect layers and vias. Due to differences in the composition, thickness and metallic density of the various layers, the substrate 20 exhibits a downward warping as shown in FIG. 2. However, the other conventional package substrates might exhibit warping in the opposite direction. Of course the amount of warping exhibited by the package substrate 20 will depend not only on its geometry and composition but also on the temperature. Due to differences in CTE between the various constituents of the package substrate, such as the polymer layers and metal interconnects, the package substrate 20 may exhibit either greater warpage or begin to flatten out with increasing temperature.

The solder balls 40a, 40b, 40c, 40d, 40e and 40f of the conventional package substrate 20 have a generally uniform diameter. Because of the downward warping, the solder balls 40a and 40f at the periphery of the package substrate 20 have an elevation z₁ (in relation to the z-axis depicted in FIG. 2), the next innermost solder balls 40b and 40e have an elevation z₂ that is slightly higher than elevation z₁ and the innermost balls 40c and 40d have a third elevation z₃ that is higher still than elevations z₁ and z₂. This staggering of elevations of the various solder balls 40a, 40b, 40c, 40d, 40e and 40f has some rather important ramifications if the semiconductor chip package 10 is slated to be mounted to another circuit board or electrical device by way of a solder reflow process. For example, and as depicted in FIG. 3, the semiconductor chip package substrate 20 may be positioned over a circuit board 65 for mounting purposes. The circuit board 65 is provided with a ball land array that consists of plural ball lands 75a, 75b, 75c, 75d, 75e and 75f and respective solder paste structures 80a, 80b, 80c, 80d, 80e and 80f that are positioned in a solder mask 82 and designed to metallurgically bond with the respective balls 40a, 40b, 40c, 40d, 40e and 40f of the package substrate 20 during a controlled collapse reflow process. Note that due to the staggered elevations z₁, z₂ and z₃ of the sets of solder balls 40a and 40f, 40b and 40e and 40c and 40d, the outermost solder balls 40a and 40f may make physical contact with the corresponding solder paste structures 80a and 80f of the circuit board 65 prior to reflow but the other pairs 40b and 40e and 40c and 40d do not make contact with their corresponding solder paste structures 80b and 80e and 80c and 80d. Of course if the gaps 85b, 85c, 85d and 85e between the solder ball 40b and solder paste structure 80b, the solder ball 40c and the solder paste structure 80c, the solder ball 40d and the solder paste structure 80d and the solder ball 40e and the solder paste structure 80e, respectively, are large enough, the solder ball 40b and solder paste structure 80b, the solder ball 40c and the solder paste structure 80c etc. may not join metallurgically during reflow, resulting in an open circuit situation and a failed interconnect pathway for the semiconductor chip 15.

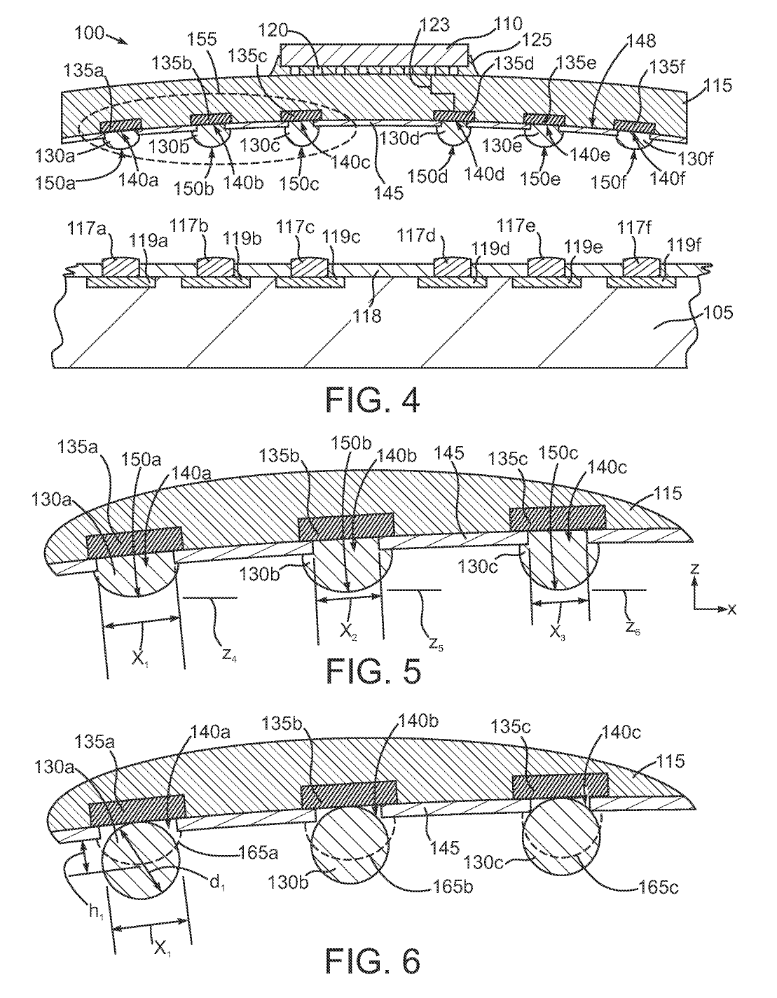

An exemplary embodiment of a semiconductor chip device 100 tailored to address the issue of warpage may be understood by referring now to FIG. 4, which shows the semiconductor chip device 100 exploded from an underlying circuit board 105. The semiconductor chip device 100 includes a semiconductor chip 110 mounted to an underlying circuit board 115. The semiconductor chip 110 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 110 may be constructed of bulk semiconductor, such as silicon or germanium, or semiconductor on insulator materials, such as silicon-on-insulator materials.

The circuit board 115 may be a semiconductor chip package substrate, a circuit card, or virtually any other type of printed circuit board. Although a monolithic structure could be used for the circuit board 115, a more typical configuration will utilize a build-up design. In this regard, the circuit board 115 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 115 can vary from four to sixteen or more, although less than four may be used. So-called “coreless” designs may be used as well. The layers of the circuit board 115 may consist of an insulating material, such as various well-known epoxies, interspersed with metal interconnects. A multi-layer configuration other than buildup could be used. Optionally, the circuit board 115 may be composed of well-known ceramics or other materials suitable for package substrates or other printed circuit boards. The circuit board 115 is provided with a number of conductor traces and vias and other structures in order to provide power, ground and signals transfers between the semiconductor chip 110 and, for example, the circuit board 105. One of those electrical pathways is depicted schematically and labeled 123.

The circuit board 105 may be a motherboard, a circuit card or virtually another type of printed wiring board, and may be composed of the same types of materials as the circuit board 115. To interface electrically with another device, such as the circuit board 115, the circuit board may include plural solder paste structures 117a, 117b, 117c, 117d, 117e and 117f in a solder mask 118 and metallurgically bonded to corresponding ball pads 119a, 119b, 119c, 119d, 119e and 119f. Optionally, the solder balls 130a, 130b, 130c, 130d, 130e and 130f could be joined directly to the pads 119a, 119b, 119c, 119d, 119e and 119f in a reflow without the solder paste structures 117a, 117b, 117c, 117d, 117e and 117f or solder mask 118. A suitable flux (not shown) could be applied to the pads 119a, 119b, 119c, 119d, 119e and 119f prior to reflow. The same joining option could be used in the other disclosed embodiments.

The semiconductor chip 110 may be flip-chip mounted to the circuit board 115 and electrically connected thereto by plural solder joints 120. Optionally, other types of interconnect structures such as conductive pillars or other types of structures may be used to interconnect the chip 110 to the circuit board 115. In this illustrative embodiment, the semiconductor chip 110 includes a partially encapsulating underfill material layer 125 that is designed to lessen the effects of differential CTE. Optionally, various types of coverings or heat spreaders may be used, such as lids composed of well-known plastics, ceramics or metallic materials as desired. Some exemplary materials include nickel plated copper, anodized aluminum, aluminum-silicon-carbide, aluminum nitride, boron nitride or the like. A resin or glob top design could also be used.

To enable the semiconductor chip device 100 to interface electrically with the circuit board 105 or some other device, the circuit board 115 is provided with a plurality of solder balls 130a, 130b, 130c, 130d, 130e and 130f that are metallurgically bonded to respective ball pads 135a, 135b, 135c, 135d, 135e and 135f. The solder balls 130a, 130b, 130c, 130d, 130e and 130f project through respective openings 140a, 140b, 140c, 140d, 140e and 140f in a solder mask 145 formed on a lower surface 148 of the circuit board 115. While only six solder balls 130a, 130b, 130c, 130d, 130e and 130f are visible, it should be understood that the circuit board 115 (and any of the other embodiments disclosed herein) may include scores, hundreds or even thousands of such solder balls. This illustrative embodiment of the circuit board 115 is depicted with a hypothetical downward warping. It should be understood that the terms “downward,” “upward,” and “vertical” used herein are intended simply to mean in some direction. In order to compensate for this downward warping, the solder balls 130a, 130b, 130c, 130d, 130e and 130f are formed so that their respective lower surfaces 150a, 150b, 150c, 150d, 150e and 150f are substantially aligned vertically. A true perfect alignment is not necessary. A goal is to avoid the undesirable substantial vertical staggering of the conventional design depicted in FIG. 2 and represented by the disparate vertical dimensions z₁, z₂ and z₃. In this way, the circuit board 115 may be mounted to the circuit board 105 such that the solder balls 130a, 130b, 130c, 130d, 130e and 130f will be, if not all in physical contact with the corresponding underlying solder paste structures 117a, 117b, 117c, 117d, 117e and 117f of the circuit board 105, certainly close to that condition prior to a reflow process.

The solder balls 130a, 130b, 130c, 130d, 130e and 130f may be fabricated with substantially aligned lower surfaces 150a, 150b, 150c, 150d, 150e and 150f in a variety of ways. In this illustrative embodiment, alignment is provided by forming the respective openings 140a, 140b, 140c, 140d, 140e and 140f in the solder mask 145 with variable dimensions to enable the solder balls 130a, 130b, 130c, 130d, 130e and 130f to expand different amounts laterally and thus compact vertically and project away from the solder mask 145 different distances in order to achieve the desired alignment of the lower surfaces 150a, 150b, 150c, 150d, 150e and 150f thereof. This concept will be explained further in conjunction with FIG. 5, which is the portion of FIG. 4 circumscribed by the dashed oval 155 shown at greater magnification. Attention is now turned also to FIG. 5. Note that because of the location of the dashed oval 155 in FIG. 4, FIG. 5 shows a small portion of the circuit board 115, the solder balls 130a, 130b and 130c, the ball pads 135a, 135b and 135c, and a small portion of the solder mask 145. However, the description herein will be applicable to the other solder balls 130d, 130e and 130f. The opening 140a may be provided with a lateral dimension x₁, the opening 140b may be provided with a lateral dimension x₂ that is smaller than x₁ and the opening 140c may be provided with a lateral dimension x₃ which is smaller still than lateral dimension x₂. The lateral dimensions x₁, x₂ and x₃ may be a width or a diameter depending upon the actual geometry of the openings 140a, 140b and 140c. The same is true albeit in a mirrored context for the openings 140d, 140e and 140f shown in FIG. 4. FIG. 5 depicts the solder balls 130a, 130b and 130c after a preliminary reflow process to establish bonding the pads 135a, 135b and 135c. At this stage the lower surface 150a of the solder ball 130a is at some elevation z₄ relative to the z-axis, and the lower surfaces 150b and 150c of the solder balls are at some elevations z₅ and z₆, which are preferably close to if not the same as z₄.

To understand how the lateral dimensions x₁, x₂ and x₃ facilitate the desired shaping of the solder balls 130a, 130b and 130c, attention is now turned to FIG. 6, which depicts the same portion of the circuit board 115 but prior to a preliminary reflow process to establish a metallurgical bond between the solder balls 130a, 130b and 130c and the underlying ball pads 135a, 135b and 135c. Prior to the application of the solder balls 130a, 130b and 130c, the solder mask 145 is subjected to a lithography process in order to establish the openings 140a, 140b and 140c with the desired lateral dimensions x₁, x₂ and x₃. Thereafter the solder balls 130a, 130b and 130c are seated on the ball pads 135a, 135b and 135c in the openings 140a, 140b and 140c. During the preliminary reflow, the solder balls 130a, 130b and 130c liquefy and expand laterally to fill the entirety of their respective openings 140a, 140b and 140c. Since the opening 140a is provided with a relatively larger lateral dimension x₁, there is more space for the solder ball 130a to expand laterally and thus compact vertically than the solder ball 130b positioned in the opening 140b with a small opening size x₂, and so on for the solder ball 130c. The ultimate shapes of the solder balls 130a, 130b and 130c are represented by the curved dashed lines 165a, 165b and 165c, respectively.

For a given circuit board 115, the warpage pattern will be generally known or easily obtained by modeling and experimentation. Accordingly, those areas in need of tailored ball and solder mask geometry will be known as well as the desired vertical dimensions of the tailored balls. For example, and as shown in FIG. 6, the solder ball 130a should have a collapse vertical dimension h₁. The dimension h₁ could be measured from the solder mask 145 or the ball pad 135a. It is necessary to be able to compute the requisite dimension x₁ of the opening 140a and the initial diameter d₁ of the solder ball 130a that will yield the desired collapse vertical dimension h₁. The following equations may be used to yield the desired quantities:

$$\begin{matrix}A = \frac{( π {d}_{n}^{3} - π {h}_{n}^{3} )}{3 {h}_{n}} \\ and & ( 1 ) \\ {d}_{n} = \sqrt[3]{\frac{( π {h}_{n}^{3} + 3 {h}_{n} A )}{π}} & ( 2 )\end{matrix}$$

where A is the area of the solder mask opening (i.e., the opening 140a in this example), dₙ, (i.e., d₁) is the diameter of the solder ball, and hₙ (i.e., h₁) is the desired collapse vertical dimension. Once the area A of the opening 140a is determined, the lateral dimension thereof may be determined. For example, if the opening 140a is circular, the lateral dimension x₁ will equal the diameter of the opening 140a, which may be determined by:

$${X}_{n} = \sqrt{\frac{4 A}{π}} \qquad ( 3 )$$

It should be understood that the selection of particular solder mask opening sizes and the locations of those openings may take on virtually any pattern or no pattern at all. A given circuit board may exhibit different levels of warping at various locations. Ball and solder mask opening geometries can be highly tailored to suit a given warping topography.

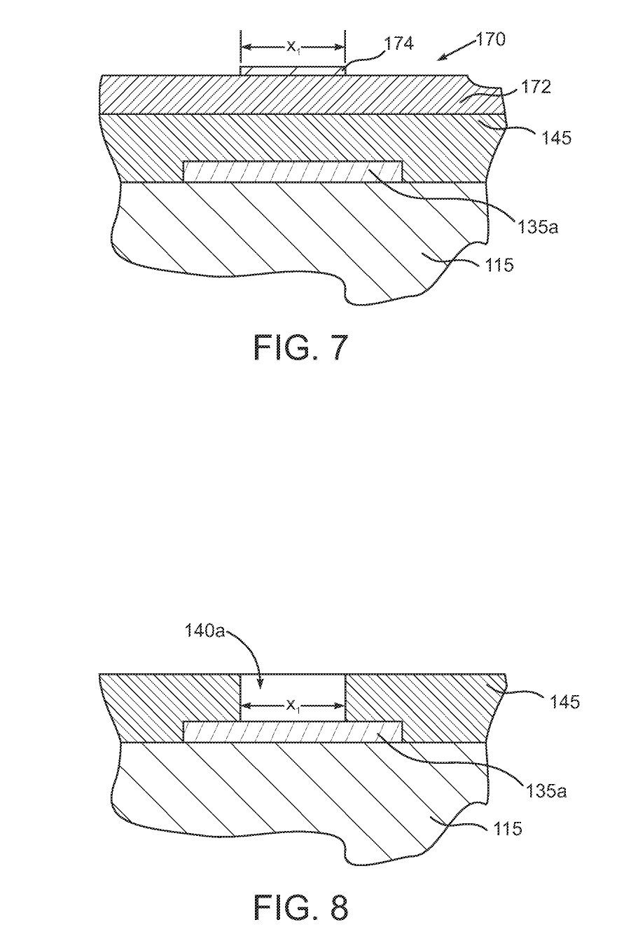

An exemplary method for fabricating the solder balls may be understood by referring now to FIGS. 7, 8 and 9 and initially to FIG. 7. The process will be described in conjunction with the solder ball 130a depicted in FIGS. 4, 5 and 6 but will be illustrative of the other balls of the circuit board 115 depicted in those figures as well. Here, FIG. 7 depicts a portion of the circuit board 115 flipped over from the orientation depicted in FIGS. 4, 5 and 6. The ball pad 135a and a portion of the solder mask 145 are shown. The ball pad 135a may be composed of a variety of conductor materials, such as aluminum, copper, silver, gold, titanium, refractory metals, refractory metal compounds, alloys of these or the like. In lieu of a unitary structure, the conductor structure ball pad 130a may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the ball pad 130a. Various well-known techniques for applying metallic materials may be used, such as physical vapor deposition, chemical vapor deposition, plating or the like. It should be understood that additional conductor structures could be used. The solder mask 145 may be fabricated from a variety of suitable materials for solder mask fabrication, such as, for example, PSR-4000 AUS703 manufactured by Taiyo Ink Mfg. Co., Ltd. or SR7000 manufactured by Hitachi Chemical Co., Ltd. At this stage, a non-contact photomask 170 may be placed on the solder mask 145. The non-contact mask includes a transparent substrate 172 and an opaque portion 174 shaped and sized according to the desired shape and size of the opening to be formed in the solder mask 145. Here, the opaque portion 174 is formed with the desire dimension x₁. Chrome or the like may be used for the opaque portion 174 and some sort of glass for the substrate 172. Optionally, photolithography mask may be formed on the solder mask 145 and patterned lithographically by well-known techniques. Thereafter, an exposure process is performed in order to expose the unmasked portions of the solder mask 145 and render them insoluble in a subsequent developing solution. Following the exposure, the mask 170 may be removed, or stripped by ashing, solvent stripping or the like if formed of resist. Next, and as shown in FIG. 8, the opening 140a may be formed with the desired lateral dimension x₁ by developing the previously exposed solder mask 145 to expose a portion of the ball pad 135a. It should be understood that the processes described herein that are performed on the circuit board 115 may be performed on a discrete circuit board or en masse on several circuit boards in strip or other forms.

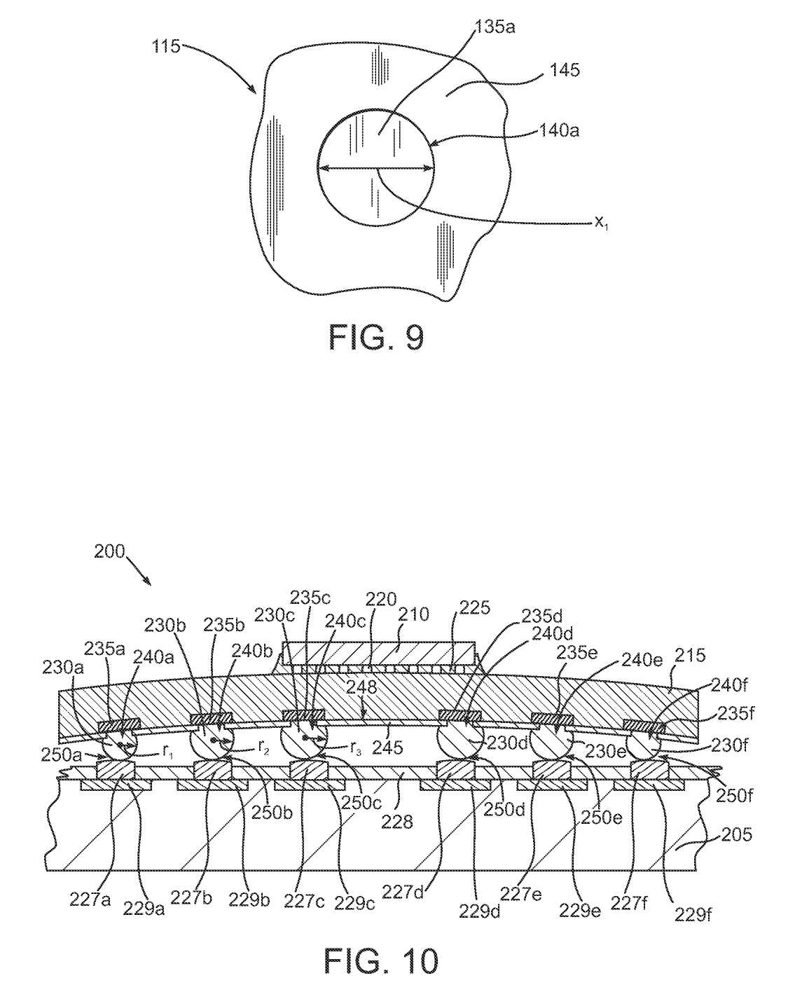

Attention is now turned to FIG. 9, which is an overhead view of the circuit board and solder mask 145 following the formation of the opening 140a. In this illustrative embodiment, the opening 140a may be formed with a circular shape that has a diameter x₁. However, a myriad of other shapes may be used for the opening 140a, such as square, rectangular, octagonal or the like. Note that a portion of the underlying ball pad 135a is clearly visible.

Following the formation of the opening 140a and the other openings 140b, 140c, 140d, 140e and 140f, the respective solder balls 130a, 130b, 130c, 130d, 130e and 130f are mounted therein and a preliminary reflow process is performed to expand the balls 130a, 130b, 130c, 130d, 130e and 130f and metallurgically bond them to the ball pads 135a, 135b, 135c, 135d, 135e and 135f depicted in FIG. 4. The solder balls 130a, 130b, 130c, 130d, 130e and 130f may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. A typical reflow process may be performed at about 240 to 250° for about 8 to 15 seconds. The temperature and time will vary depending on the solder compositions and sizes, the geometry of the circuit board 115 and other variables.

With the solder balls 130a, 130b, 130c, 130d, 130e and 130f in place, the circuit board 115 may be mounted to the circuit board 105 by matching up the respective solder balls 130a, 130b, 130c, 130d, 130e and 130f and solder paste structures 117a, 117b, 117c, 117d, 117e and 117f and a subsequent reflow process performed. The more substantial vertical alignment of the lower surfaces 150a, 150b, 150c, 150d, 150e and 150f of the balls 130a, 130b, 130c, 130d, 130e and 130f will more reliably produce metallurgical bonding between the mating sets of balls. A reflow process is next performed to fuse the matching solder balls. A typical reflow process may be performed at about 240 to 250° for about 8 to 15 seconds. The temperature and time will vary depending on the solder compositions, sizes and the geometries of the circuit boards 115 and 105 and other variables.

As noted elsewhere herein, achieving a more favorable vertical alignment of lower surfaces of plural solder balls on a circuit board may be achieved in a variety of ways. In this regard, FIG. 10 depicts an alternate exemplary embodiment of a semiconductor chip device 200 which may be mounted to another circuit board 205. In this illustrative embodiment, the semiconductor chip device 200 may include a semiconductor chip 210 mounted to a circuit board 215 by way of plural solder joints 220 or the other types of interconnect structures described elsewhere herein. Again, the chip 210 may be partially encapsulated by an underfill material 225 if desired. The circuit board 205 may be provided with plural solder paste structures 227a, 227b, 227c, 227d, 227e and 227f positioned in a solder mask 228 and mounted to respective ball pads 229a, 229b, 229c, 229d, 229e and 229f. The circuit board 215 may be configured very much like the circuit board 115 with a few notable differences. The circuit board 215 may include a ball grid array that consists of plural solder balls 230a, 230b, 230c, 230d, 230e and 230f that are metallurgically bonded to respective ball pads 235a, 235b, 235c, 235d, 235e and 235f. The solder balls 230a, 230b, 230c, 230d, 230e and 230f may project through respective openings 240a, 240b, 240c, 240d, 240e and 240f in a solder mask 245 formed on the lower surface 248 of the circuit board 215. The openings 240a, 240b, 240c, 240d, 240e and 240f may be formed with substantially the same lateral dimension. In order to achieve the desired substantial planar alignment of the solder balls 230a, 230b, 230c, 230d, 230e and 230f, the individual or groups of the solder balls 230a, 230b, 230c, 230d, 230e and 230f may be formed with different initial vertical dimensions so that the lower surfaces 250a, 250b, 250c, 250d, 250e and 250f achieve substantial vertical alignment. In this regard, the vertical dimension might be, for example, an uncollapsed diameter or radius of a given ball in the case where the balls 230a, 230b, 230c, 230d, 230e and 230f are indeed spherical or some other dimension, such as a height, in the event that the solder balls 230a, 230b, 230c, 230d, 230e and 230f are not strictly spherical but perhaps cylindrical in shape. Thus, the balls 230a and 230f in this example may have a radius r₁, the balls 230b and 230e may have a radius of r₂ that is larger than r₁ and so on for the radius r₃ of the balls 230c and 230d. By manufacturing the balls 230a, 230b, 230c, 230d, 230e and 230f with staggered vertical dimensions, a better vertical alignment of the lower surfaces 250a, 250b, 250c, 250d, 250e and 250f thereof may be achieved so that when the circuit board 215 is mounted to the circuit board 205 the balls 230a, 230b, 230c, 230d, 230e and 230f match up vertically more favorably with the underlying solder paste structures 227a, 227b, 227c, 227d, 227e and 227f.

As with the other embodiments disclosed herein, the warping of the circuit board 215 may be mapped and the geometry of the solder balls 230a, 230b, 230c, 230d, 230e and 230f tailored according to whatever warping pattern the circuit board 215 exhibits. It may be that one lateral side or just some few portions of the circuit board exhibit warpage. In those instances, ball geometry on a given portion of the circuit board 215 may be tailored to address the particular warping pattern.

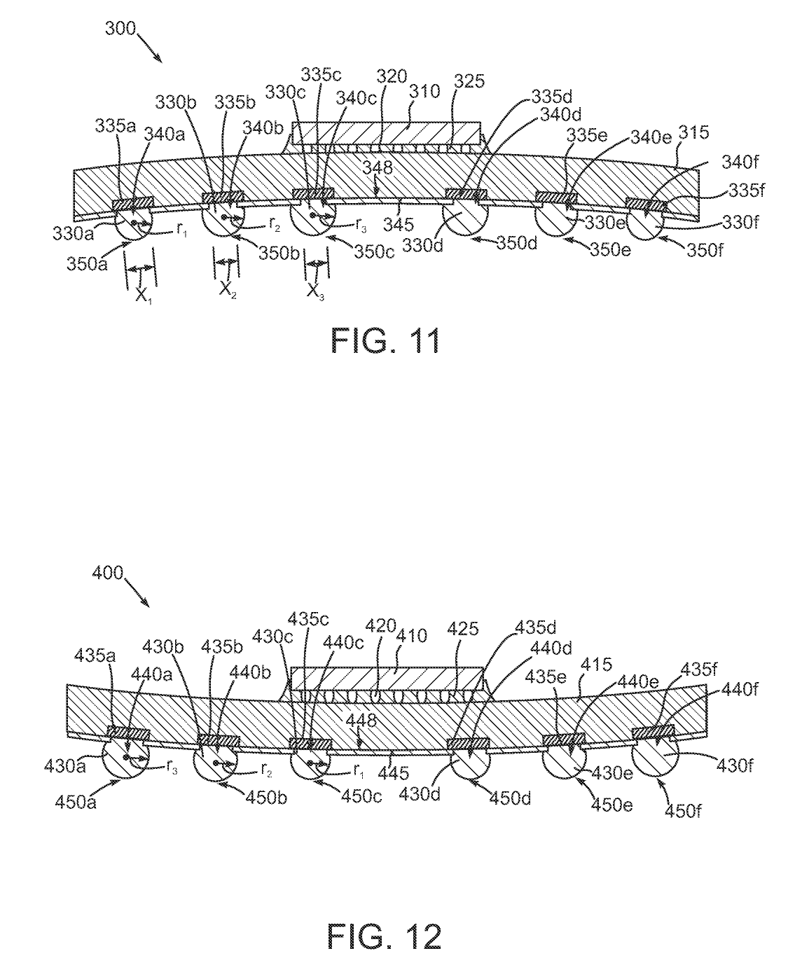

In another alternate exemplary embodiment depicted in section in FIG. 11, attributes of both the aforementioned embodiments, that is, variable solder mask opening size and variable solder ball size may be incorporated into a single circuit board for purposes of achieving a substantial vertical alignment of solder ball lower surfaces. Here, the exemplary semiconductor chip device 300 may include a semiconductor chip 310 mounted to a circuit board 315. The chip 310 and the circuit board 315 may be configured as substantially described elsewhere herein for the other embodiments. Plural solder joints 320 and an underfill layer 325 may be utilized. The circuit board 315 is provided with plural solder balls 330a, 330b, 330c, 330d, 330e and 330f with staggered vertical dimensions r₁, r₂ and r₃. The balls 330a, 330b, 330c, 330d, 330e and 330f are mounted to respective ball pads 335a, 335b, 335c, 335d, 335e and 335f of the circuit board 315 and project through respective openings 340a, 340b, 340c, 340d, 340e and 340f in a solder mask 345 formed on a lower surface 348 of the circuit board 315. The openings 340a, 340b, 340c, 340d, 340e and 340f may be provided with staggered lateral dimensions such as x₁, x₂ and x₃ as described elsewhere herein. The combination of staggered vertical dimensions for the balls 330a, 330b, 330c, 330d, 330e and 330f and lateral dimensions x₁, x₂ and x₃ for the solder mask openings 340a, 340b, 340c, 340d, 340e and 340f may provide yet another way to achieve a substantial vertical alignment of the lower surfaces 350a, 350b, 350c, 350d, 350e and 350f of the balls 330a, 330b, 330c, 330d, 330e and 330f. As with the other embodiments disclosed herein, the warping of the circuit board 315 may be mapped and the geometry of the solder balls 330a, 330b, 330c, 330d, 330e and 330f tailored according to whatever warping pattern the circuit board 315 exhibits.

In the foregoing illustrative embodiments, a downward warping of a semiconductor chip circuit board is depicted. However, it should be understood that depending upon the configuration of a particular circuit board, a warping in the opposite direction may result. However, techniques consistent with the embodiments disclosed herein may be utilized in order to address the issue of warpage in an upward direction that is in a direction opposite to the downward direction depicted in the other embodiments. In this regard, attention is now turned to FIG. 12, which is a sectional view of a semiconductor chip device 400 that includes a semiconductor chip 410 mounted on a circuit board 415. The semiconductor chip 410 and circuit board 415 may be configured as substantially described elsewhere herein. In this regard, plural solder joints 420 may be used to interconnect the chip 410 to the circuit board 415 and an underfill material layer 425 may be used to address differential CTE as desired. Here, the circuit board 415 is illustrated with an upward warping. To interconnect the circuit board 415 to another device, the circuit board 415 is provided with plural solder balls 430a, 430b, 430c, 430d, 430e and 430f that are metallurgically bonded to respective ball pads 435a, 435b, 435c, 435d, 435e and 435f and project through respective openings 440a, 440b, 440c, 440d, 440e and 440f in a solder mask 445 that is formed on a lower surface 448 of the circuit board 415. An improved vertical alignment of the lower surfaces 450a, 450b, 450c, 450d, 450e and 450f of the balls 430a, 430b, 430c, 430d, 430e and 430f may be achieved in the event of the upward warping depicted in FIG. 12 by fabricating the outermost balls 430a and 430f with a relatively larger vertical dimension r₃ and the next innermost balls 430b and 430e with somewhat lesser dimensioned r₂ and the inner balls with the dimension of r₁ in turn. Of course the staggering of vertical dimensions could be combined with a selection of variable lateral dimensions of the openings 440a, 440b, 440c, 440d, 440e and 440f as described elsewhere herein with regard to the other illustrative embodiments. Again, the openings 440a, 440b, 440c, 440d, 440e and 440f may be fabricated as described elsewhere herein. As with the other embodiments disclosed herein, the warping of the circuit board 415 may be mapped and the geometry of the solder balls 430a, 430b, 430c, 430d, 430e and 430f tailored according to whatever warping pattern the circuit board 415 exhibits.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
applying a solder mask to a first side of a first circuit board, the first side including a first conductor structure and a second conductor structure; and
forming a first opening in the solder mask that extends to the first conductor structure and has a first area and a second opening that extends to the second conductor structure and has a second area larger than the first area.

2. The method of claim 1, comprising coupling a semiconductor chip to a second side of the first circuit board.

3. The method of claim 1, comprising coupling a first solder structure to the first conductor structure and a second solder structure to the second conductor structure.

4. The method of claim 3, wherein the first solder structure includes a first surface projecting away from the solder mask a first distance and the second solder structure includes a second surface projecting away from the solder mask a second distance.

5. The method of claim 4, wherein the first and second distances are not the same.

6. The method of claim 1, comprising forming the first and second openings using instructions stored in a computer readable medium.

7. The method of claim 1, wherein the first and second openings are formed by photolithography.

8. A method of manufacturing, comprising:
applying a solder mask to a first side of a first circuit board, the first side including a first conductor structure and a second conductor structure;
forming a first opening in the solder mask that extends to the first conductor structure and a second opening in the solder mask that extends to the second conductor structure;
coupling a first solder structure to the first conductor structure wherein the first solder structure is positioned at least partially in the first opening and includes a first surface projecting away from the solder mask a first distance; and
coupling a second solder structure to the second conductor structure wherein the second solder structure is positioned at least partially in the second opening and includes a second surface projecting away from the solder mask a second distance greater than the first distance.

9. The method of claim 8, wherein the first solder structure comprise a first ball having a first uncollapsed diameter and the second solder structure comprises a second ball having a second uncollapsed diameter greater than the first uncollapsed diameter.

10. The method of claim 8, wherein the first opening includes a first area and the second opening includes a second area different the first area.

11. The method of claim 8, comprising forming the first and second openings using instructions stored in a computer readable medium.

12. The method of claim 8, wherein the first and second openings are formed by photolithography.

13. An apparatus, comprising:
a first circuit board including a first side and second side opposite the first side, the first side including a first conductor structure and a second conductor structure; and
a solder mask positioned on the first side and including a first opening that extends to the first conductor structure and has a first area and a second opening that extends to the second conductor structure and has a second area larger than the first area.

14. The apparatus of claim 13, comprising a semiconductor chip coupled to the second side of the first circuit board.

15. The apparatus of claim 13, comprising a first solder structure coupled to the first conductor structure and including a first surface projecting away from the solder mask a first distance and a second solder structure coupled to the second conductor structure and including a second surface projecting away from the solder mask a second distance.

16. The apparatus of claim 15, wherein the first and second distances are substantially the same.

17. The apparatus of claim 15, wherein the first solder structure has a first uncollapsed diameter and the second solder structure has a second uncollapsed diameter that is different than the first uncollapsed diameter.

18. An apparatus, comprising:
a first circuit board including a first side and a second side opposite the first side, the first side including a first conductor structure and a second conductor structure;
a solder mask positioned on the first side and including a first opening extending to the first conductor structure and a second opening extending to the second conductor structure;
a first solder structure coupled to the first conductor structure, positioned at least partially in the first opening, and including a first surface projecting away from the solder mask a first distance; and
a second solder structure coupled to the second conductor structure, positioned at least partially in the second opening and including a second surface projecting away from the solder mask a second distance greater than the first distance.

19. The apparatus of claim 18, wherein the first solder structure comprise a first ball having a first uncollapsed diameter and the second solder structure comprises a second ball having a second uncollapsed diameter greater than the first uncollapsed diameter.

20. The apparatus of claim 18, comprising a semiconductor chip coupled to the second side of the first circuit board.
